(19) United States
(12) Patent Application Publication
(10) Pub. No.: US 2018/0054919 A1
(43) Pub. Date: Feb. 22, 2018

(54) REFRIGERANT SUPPLY DEVICE, PHASE-CHANGE COOLING APPARATUS EQUIPPED WITH THE SAME, AND METHOD OF SUPPLYING REFRIGERANT

(71) Applicant: NEC Corporation, Tokyo (JP)

(72) Inventors: Minoru YOSHIKAWA, Tokyo (JP); Masanori SATO, Tokyo (JP); Akira SHOUJIGUCH!, Tokyo (JP); Arihiro MATSUNAGA, Tokyo (JP); Masaki CHIBA, Tokyo (JP)

(21) Appl. No.: 15/557,709

(22) PCT Filed: Mar. 9, 2016
(86) PCT No.: PCT/JP2016/001300

§ 371 Date: Sep. 12, 2017

(30) Foreign Application Priority Data
Mar. 13, 2015 (JP) 2015-051064

(51) Int. Cl. H05K 7/20; G06F 1/20; F28D 15/06

(52) U.S. Cl. CPC H05K 7/20327; F28D 15/06; G06F 1/20

(57) ABSTRACT

To address the problem of deterioration of cooling performance of a phase-change cooling apparatus cooling a plurality of heat-emitting bodies because of changes in the amount of heat emitted by the plurality of heat-emitting bodies, a refrigerant supply device according to the present invention includes: a first reservoir for storing refrigerant liquid caused to flow by a drive pump; and a refrigerant liquid amount adjustment means for adjusting the flow rate of the refrigerant liquid flowing out of the first reservoir to a heat reception unit wherein the reservoir includes a branch outlet, wherein the branch outlet is provided in a position higher than the refrigerant liquid amount adjustment means, and wherein refrigerant liquid stored in the first reservoir flows out of the branch outlet to a second reservoir disposed in a position lower than the first reservoir.

### TECHNICAL FIELD

The present invention relates to a refrigerant supply device, a phase-change cooling apparatus equipped with the same, and a method of supplying refrigerant and, in particular, relates to a refrigerant supply device used for a cooling apparatus that transport and discharge heat by refrigerant in a cycle of evaporation and condensation, a phase-change cooling apparatus equipped with the same, and a method of supplying refrigerant.

### BACKGROUND ART

In recent years, data centers, in which servers and network equipment are concentrated in one place, have been playing an increasingly important role as the internet and other services expand. The electricity consumption by data centers has been increasing as more and more data is processed. In data centers, the electric power consumed by air conditioners for cooling the electronic appliances is especially large, accounting for nearly a half of the total electricity consumption by data centers. It is hence desired to reduce the electric power consumed by data centers. As a means for satisfying this need, attempts have been made to utilize techniques of directly transporting heat discharged from the rack containing electronic appliances to the outside of the building and discharging the heat into the open air, without the help of an air conditioner.

Methods of transporting heat discharged from the rack include, apart from a method employing circulated cold water, a method utilizing the phenomenon of phase changes of refrigerant. This method utilizes refrigerant in a cycle of evaporation and condensation for transporting and discharging heat and is characterized by transportation of a large amount of heat, enabled by the utilization of latent heat at the time of phase changes of refrigerant between liquid phase and gas phase. The technique is considered promising as a means for reducing electricity consumption by the air conditioners used in data centers.

PTL 1 discloses an example of such a cooling device based on refrigerant circulation cycle utilizing phase changes of refrigerant.

The cooling system for electronic appliances according to a related art disclosed in PTL 1 has an evaporator disposed near the server. A cooling coil is provided in the evaporator and the refrigerant liquid flowing in the cooling coil evaporates due to the heated air discharged by the server and absorbs heat of evaporation from the environment during this gasification. The evaporator is provided with a temperature sensor to measure the temperature of the air heated and discharged by the server and cooled by the evaporator. At the inlet of the cooling coil, an expansion valve is provided for adjusting the flow rate of the refrigerant supplied to the cooling coll. The degree of opening of the expansion valve is automatically adjusted based on the temperature measured by the temperature sensor.

This configuration allows the opening of the expansion valve to be narrowed to reduce the flow rate of the refrigerant being supplied when the temperature of the air cooled by the evaporator gets lower than a preset temperature. The cooling system for electronic appliances according to the related art thus enables the efficient cooling at a small running cost of electronic appliances emitting a large amount of heat, according to the inventors.

### CITATION LIST

### Patent Literature

[PTL 1] Japanese Unexamined Patent Application Publication No. 2012-146331 (paragraphs [0021] to [0026])

### SUMMARY OF INVENTION

### Technical Problem

As described above, the cooling system for electronic appliances according to the related art disclosed in PTL 1 is configured to adjust the amount of refrigerant supply in response to the load. This is for supplying the refrigerant at such a flow rate that the latent heat of the supplied refrigerant matches the amount of heat discharged from the rack. This is because, when the flow rate is not large enough for providing the required latent heat, refrigerant liquid will be in short supply in the downstream of the refrigerant path in the heat reception unit, which precludes phase changes and heat absorption from happening. When the flow rate is more than enough to provide the required latent heat, refrigerant liquid is in excessive supply, resulting in a liquid cooling by sensible heat, which causes a temperature rise in the downstream, the magnitude of the temperature rise being determined by the heat capacity of the refrigerant liquid. This lowers the heat exchange efficiency and hinders sufficient heat absorption.

The above-described cooling system for electronic appliances according to the related art has a disadvantage in dealing with a plurality of electronic appliances with changing loads, such as servers. When the load on the servers contained in the rack changes, the heat absorbing performance of the system deteriorates. Increasing the load on the air conditioning. The cause of this is as follows.

The cooling system for electronic appliances according to the related art is configured to supply refrigerant to server racks containing a plurality of servers, adjusting the flow rate of the refrigerant for individual racks. It follows that the refrigerant is supplied at a flow rate suitable for ensuring required latent heat only after the amount of load on the whole rack is recognized. However, since refrigerant to provide the latent heat is supplied at a small flow rate, the amount of refrigerant supply cannot be timely adjusted when the load on the servers changes. This results in a deterioration of heat absorbing performance.

The development of energy saving technology has led to the processors and the like in a server configured to widely change the load, and hence electricity consumption, in response to changes in the amount of data processing. In the cooling system for electronic appliances according to the related art, the heat absorbing performance deteriorates every time the load changes because of the reasons described above. As a result, the load on the air conditioner in the server room increases.

As described above, phase-change cooling apparatuses cooling a plurality of beat-emitting bodies have a disadvantage in that the cooling performance deteriorates due to changes in the amount of heat emission by a plurality of heat-emitting bodies.

An object of the present invention is to provide a refrigerant supply device that solves the above-described problem, i.e., the problem of deteriorating cooling performance of a phase-change cooling apparatus cooling a plurality of heat-emitting bodies due to changes in the amount of heat emission by the plurality of heat-emitting bodies, as well as to provide a phase-change cooling apparatus equipped with the same and a method of supplying refrigerant.

### Solution to Problem

A refrigerant supply device according to the present invention includes: a first reservoir for storing refrigerant liquid caused to flow by a drive pump; and a refrigerant liquid amount adjustment means for adjusting the flow rate of the refrigerant liquid flowing out of the first reservoir to a heat reception unit, wherein the reservoir comprises a branch outlet, wherein the branch outlet is provided in a position higher than the refrigerant liquid amount adjustment means, and wherein refrigerant liquid stored in the first reservoir flows out of the branch outlet to a second reservoir disposed in a position lower than the first reservoir.

A phase-change cooling apparatus equipped with refrigerant supply devices according to the present invention includes: a plurality of heat reception units containing refrigerant and disposed in a vertical direction; a heat discharge unit for discharging heat that the refrigerant receives in the heat reception units, refrigerant liquid flowing out of the heat discharge unit; a drive pump to cause the refrigerant liquid to flow; and a plurality of refrigerant supply devices that respectively supply the refrigerant liquid to the plurality of heat reception units, wherein each of the refrigerant supply devices includes: a first reservoir for storing the refrigerant liquid caused to flow by the drive pump; and a refrigerant liquid amount adjustment means for adjusting a flow rate of the refrigerant liquid flowing out of the first reservoir to a heat reception unit, wherein the first reservoir includes a branch outlet, wherein the branch outlet is provided in a position higher than the refrigerant liquid amount adjustment means, and wherein refrigerant liquid stored in the first reservoir flows out of the branch outlet to a second reservoir disposed in a position lower than the first reservoir.

A method of supplying refrigerant according to the present invention includes: retaining reserve refrigerant liquid, which is refrigerant liquid caused to flow by a drive pump and stored; controlling a flow rate of circulating refrigerant liquid, which is part of the reserve refrigerant liquid and flows to a heat reception region: and causing part of the reserve refrigerant liquid to flow downward in a vertical direction from a vicinity of the liquid surface of the reserve refrigerant liquid.

### Advantageous Effects of Invention

A refrigerant supply device of the present invention, a phase-change cooling apparatus equipped with the same, and a method of supplying refrigerant prevent the deterioration of cooling performance even when a plurality of heat-emitting bodies are cooled and the amount of heat emission by the plurality of heat-emitting bodies changes.

### BRIEF DESCRIPTION OF DRAWINGS

FIG. 1 is a cross sectional view illustrating a configuration of a refrigerant supply structure according to a first exemplary embodiment of the present invention.

FIG. 2 is a schematic view illustrating an outline of a phase-change cooling apparatus according to a second exemplary embodiment of the present invention, disposed in a data center building.

FIG. 3 is a perspective view of an outlook of a rack containing a heat reception unit module included in the phase-change cooling apparatus according to the second exemplary embodiment of the present invention and electronic appliances.

FIG. 4 is a front view schematically illustrating a configuration of a heat reception unit module included in the phase-change cooling apparatus according to the second exemplary embodiment of the present invention.

FIG. 5 is a schematic view for illustrating the circulation of the refrigerant in a heat reception unit module according to the second exemplary embodiment of the present invention.

FIG. 6 schematically illustrates the temperature distribution of the air discharged from a heat reception unit included in the phase-change cooling apparatus according to the second exemplary embodiment of the present invention.

FIG. 7 illustrates the relation between the degree of opening of valves and the position of valves in a heat reception unit module of a related art.

FIG. 8 illustrates the relation between the degree of opening of valves and the position of valves in a heat reception unit module according to the second exemplary embodiment of the present invention.

FIG. 9 is a front view schematically illustrating a configuration of a heat reception unit module included in a phase-change cooling apparatus according to a third exemplary embodiment of the present invention.

FIG. 10 is a front view schematically illustrating another configuration of the heat reception unit module included in the phase-change cooling apparatus according to the third exemplary embodiment of the present invention.

FIG. 11 is a schematic view illustrating an outline of a phase-change cooling apparatus according to a fourth exemplary embodiment of the present invention, disposed in a data center building.

### DESCRIPTION OF EMBODIMENTS

With reference to the attached drawings, embodiments of the present invention will be described hereinbelow.

### First Exemplary Embodiment

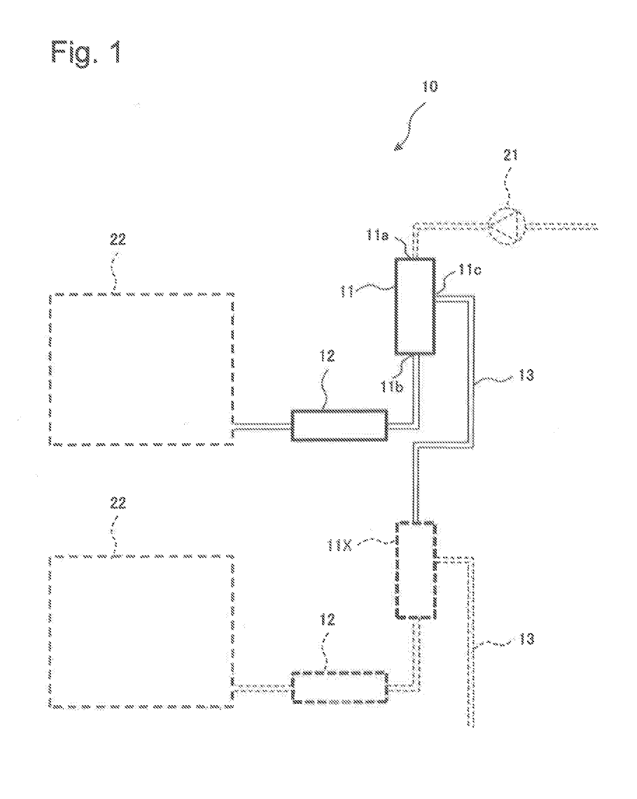

FIG. 1 is a cross sectional view illustrating a configuration of a refrigerant supply device according to a first exemplary embodiment of the present invention. The refrigerant supply device (refrigerant supply structure) 10 according to the present exemplary embodiment includes a reservoir 11 and a refrigerant liquid amount adjustment means 12.

The reservoir 11 stores refrigerant liquid caused to flow by a drive pump 21. The refrigerant liquid amount adjustment means 12 controls the flow rate of the refrigerant liquid flowing out of the reservoir 11 to a heat reception unit 22. The reservoir 11 includes a branch outlet 11c, and the branch outlet 11c is disposed in a higher position than the refrigerant liquid amount adjustment means 12. Refrigerant liquid stored in the reservoir 11 flows out of the branch outlet 11c to another reservoir 11X disposed in a lower position than the reservoir 11.

The branch outlet 11c may be connected with a branch pipe 13 for transporting refrigerant liquid in the reservoir 11 from the vicinity of the liquid surface of the refrigerant liquid in the reservoir 11 to another reservoir 11X. More specifically, the branch pipe 13 is for transporting refrigerant liquid in the reservoir 11 from the vicinity of the liquid surface of the refrigerant liquid in the reservoir 11 to another reservoir 11X provided in a position lower than the reservoir 11 in a vertical direction.

Although FIG. 1 illustrates a configuration in which the refrigerant liquid amount adjustment means 12 is provided for a pipe connected to the bottom surface of the reservoir 11, the refrigerant liquid amount adjustment means 12 may be configured in a differently manner and may be provided for a pipe connected to a lower end of a side surface of the reservoir 11.

The heat reception unit 22 contains refrigerant and receives heat from heat-emitting bodies, and the refrigerant liquid evaporates because of the heat. The refrigerant supply structure 10 according to the present exemplary embodiment has a configuration in which the reservoir 11 stores refrigerant liquid, and the refrigerant liquid is supplied from the reservoir 11 via the refrigerant liquid amount adjustment means 12 to the heat reception unit 22. The reservoir 11 hence serves as a buffer to a change in the amount of refrigerant liquid in the heat reception unit 22. Therefore, even with a sudden change in the amount of heat emitted by the heat-emitting bodies, the heat reception unit 22 will have no excess or shortage in the amount of the refrigerant liquid.

The refrigerant supply structure 10 according to the present exemplary embodiment has a configuration in which the refrigerant liquid in the reservoir is transported through the branch pipe 13 to another reservoir 11X located in a lower position. Because of this, even when refrigerant liquid is supplied to a plurality of heat reception units 22 corresponding to a plurality of heat-emitting bodies, changes in the amount of heat absorbed by a part of the heat reception units 22 will not cause any excess or shortage in the amount of the refrigerant liquid supplied to the other heat reception units 22.

As described above, the refrigerant supply structure 10 according to the present exemplary embodiment prevents deterioration of cooling performance even when a plurality of heat-emitting bodies are cooled and the amount of heat emitted by the plurality of heat-emitting bodies changes.

The reservoir 11 may be configured to include an inlet 11a into which the refrigerant liquid flows, an outlet 11b of which the refrigerant liquid flows out toward the heat reception unit 22, and a branch outlet 11c connected with a branch pipe 13. The refrigerant liquid amount adjustment means 12 is connected to the outlet 11b. The reservoir 11 may be configured to have a capacity large enough at least to contain a volume of the refrigerant liquid such that the total amount of heat of evaporation of the volume of the refrigerant liquid is equal to the maximum amount of heat receivable by the heat reception unit 22.

The refrigerant liquid amount adjustment means 12 may be configured to control the flow rate of the refrigerant, liquid in such a way that the heat reception unit 22 has substantially equal cooling characteristics at different points along a direction in which the refrigerant liquid flows. Specifically, a cooling characteristic of the heat reception unit 22 may be the temperature of the air discharged from the heat reception unit 22.

Typically, the refrigerant liquid amount adjustment means 12 is a variable flow valve.

The refrigerant liquid amount adjustment means 12 may be a pipe connecting the heat reception unit 22 with the reservoir 11. In such a case, the pipe may include a part having an inner diameter different from the inner diameter of another pipe connecting the reservoir 11X with another heat reception unit. The refrigerant liquid amount adjustment means 12 may be configured in a different manner as long as different pressure losses are provided for refrigerant liquid. More specifically, for example, the pipes may have different lengths, different radii of curvature, or different coefficients of friction for the inner walls.

Next, a method of supplying refrigerant according to the present exemplary embodiment will be described.

The method of supplying refrigerant according to the present exemplary embodiment is implemented by, first, retaining reserve refrigerant liquid, which is refrigerant liquid caused to flow by a drive pump and stored, and controlling the flow rate of circulating refrigerant liquid, which is a part of the reserve refrigerant liquid and flows to a heat reception region. Further, part of the reserve refrigerant liquid is caused to flow downward in a vertical direction from a vicinity of the liquid surface of the reserve refrigerant liquid.

The flow rate of circulating refrigerant liquid may be controlled in such a way that the heat reception region has substantially equal cooling characteristics at different points along a direction in which the circulating refrigerant liquid flows. Further, the circulating refrigerant liquid may be caused to flow toward each of a plurality of heat reception regions disposed in a vertical direction, wherein a control is performed in such a way that a heat reception region disposed in a lower position in a vertical direction has a greater pressure loss for the circulating refrigerant liquid flowing into the heat reception region and that the lower the position is, the greater the pressure loss is.

As described above, the refrigerant supply structure 10 and the method of supplying refrigerant according to the present exemplary embodiment prevent deterioration of cooling performance even when a plurality of heat-emitting bodies are cooled and the amount of heat emitted by the plurality of heat-emitting bodies changes.

### Second Exemplary Embodiment

Next, a second exemplary embodiment of the present invention will be described. As for the present exemplary embodiment, a phase-change cooling apparatus equipped with refrigerant supply structures 10 according to the first exemplary embodiment will be described. Hereinbelow, descriptions will be made, as an example, as to a phase-change cooling apparatus 100 equipped with refrigerant supply structures 10, which is contained in a server rack disposed in a data center (DC) or the like. In the following descriptions the “phase-change cooling apparatus 100 equipped with refrigerant supply structures 10” will be simply referred to as the “phase-change cooling apparatus 100”.

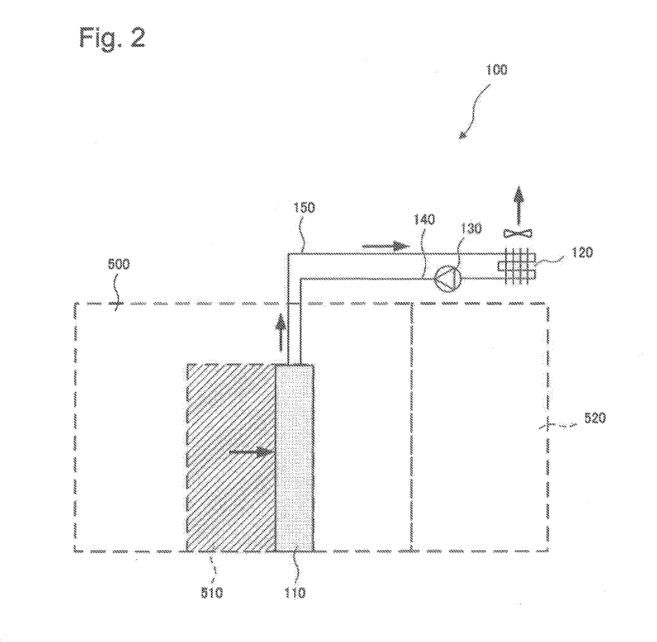

FIG. 2 is a schematic view illustrating an outline of a phase-change cooling apparatus 100 according to the present exemplary embodiment, disposed in a data center building.

The phase-change cooling apparatus 100 according to the present exemplary embodiment includes a heat reception unit module 110, a heat discharge unit 120, and a drive pump 130. The heat reception unit module 110 includes a plurality of heat reception units containing refrigerant and disposed in a vertical direction and a plurality of refrigerant supply structures that respectively supply refrigerant liquid to the plurality of heat reception units. The heat discharge unit 120 discharges heat that the refrigerant receives in the heat reception unit and refrigerant liquid flows out of the heat discharge means. The drive pump 130 causes the refrigerant liquid to flow toward the heat reception unit module 110.

In a server room 500 of a data center or the like, a housing (a rack) 510 containing a plurality of electronic appliances 511 is disposed and data processing is performed. The electronic appliances 511 generate heat because of the load such as data processing and the heat is discharged by means of air to the outside of the rack 510.

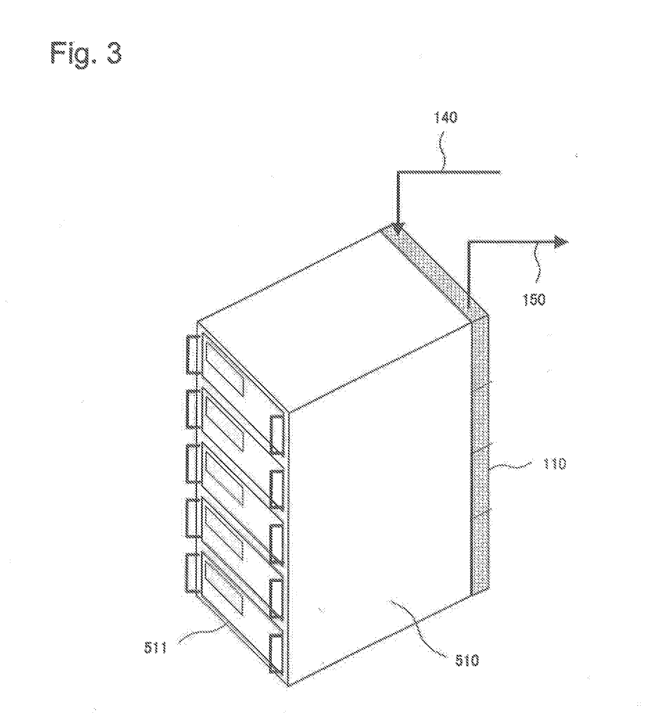

The phase-change cooling apparatus 100 according to the present exemplary embodiment is configured in such a way that the plurality of heat reception units are disposed in a housing (rack) 510 containing the electronic appliances 511 as objects to be cooled. In other words, the heat reception unit module 110 included in the phase-change cooling apparatus 100 is disposed on the air discharging side of the rack 510, for example, on the side of the door from which the air is discharged. The heat reception unit module 110 is connected via a liquid pipe 140 and a vapor pipe 150 with a heat discharge unit 120, which is disposed in, for example, a machine room 520 located outside of and adjacent to the server room 500 or outdoors. The above-described drive pump 130 is disposed in the flow path of the liquid pipe 140 and transports refrigerant liquid between the heat discharge unit 120 and the heat reception unit module 110. FIG. 3 illustrates an outlook of a rack 510 installed with a heat reception unit module 110 according to the present exemplary embodiment and the electronic appliances 511.

The heat generated in the electronic appliances 511 is discharged from the heat discharge unit 120 directly to the outside of the server room 500. This reduces the amount of heat that the air conditioner in the server room 500 disposes of in the cooling process and thereby reduces the load on the air conditioner. The arrows in FIG. 2 indicate the transportation of the heat generated in the electronic appliances 511.

The refrigerant to be used for the phase-change cooling apparatus 100 may be, for example, a refrigerant with a low boiling point, such as hydrofluorocarbon (HFC) or hydrofluoroether (HFE). By removing the air by evacuation after filling the refrigerant, the refrigerant is used in an environment under the saturated vapor pressure.

The refrigerant in the heat reception unit module 110 changes phase from liquid to gas by the presence of heat discharged from the electronic appliances 511, the heat being absorbed for heat of evaporation. The evaporated refrigerant, or refrigerant vapor transports heat through the vapor pipe 150 to the heat discharge unit 120. In the heat discharge unit 120, the refrigerant vapor discharges heat by heat exchange to the open air or to cold water and changes phase again to liquid, becoming refrigerant liquid. The refrigerant liquid is caused to flow through the liquid pipe 140 back to the heat reception unit module 110 by the driving force of the drive pump 130.

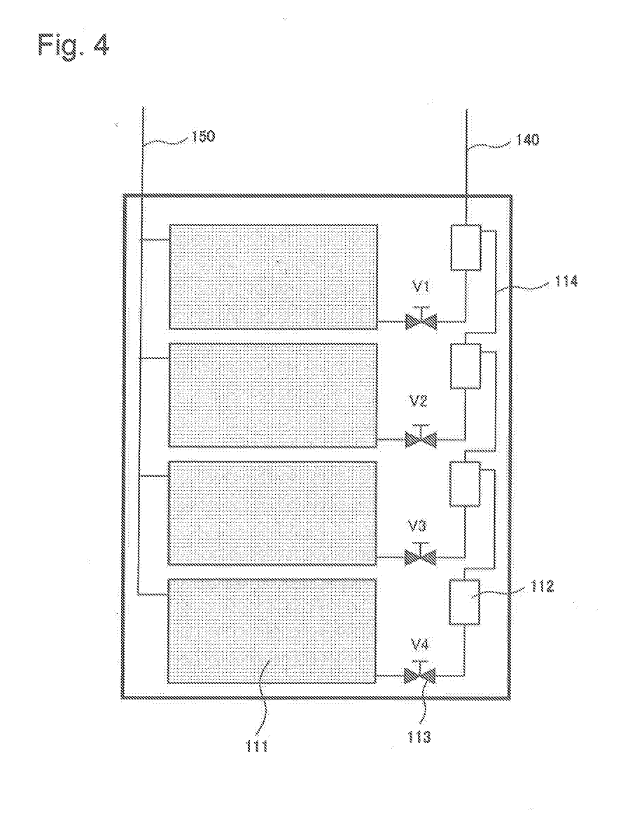

FIG. 4 illustrates a configuration of the heat reception unit module 110.

The heat reception unit module 110 includes a plurality of heat reception units 111, and each of the heat reception units 111 is provided with a reserve tank 112 serving as a reservoir, a valve 113 serving as a refrigerant liquid amount adjustment means, and a branch pipe 114.

The heat reception units 111 exchange heat between the heated air discharged by the electronic appliances 511 and the refrigerant. The reserve tanks 112 serve as buffers by temporarily storing refrigerant liquid. The valves 113 are disposed between the heat reception units 111 and the reserve tanks 112 and adjust the flow rates of the refrigerant liquid.

Next, an operation of the phase-change cooling apparatus 100 according to the present exemplary embodiment will be described.

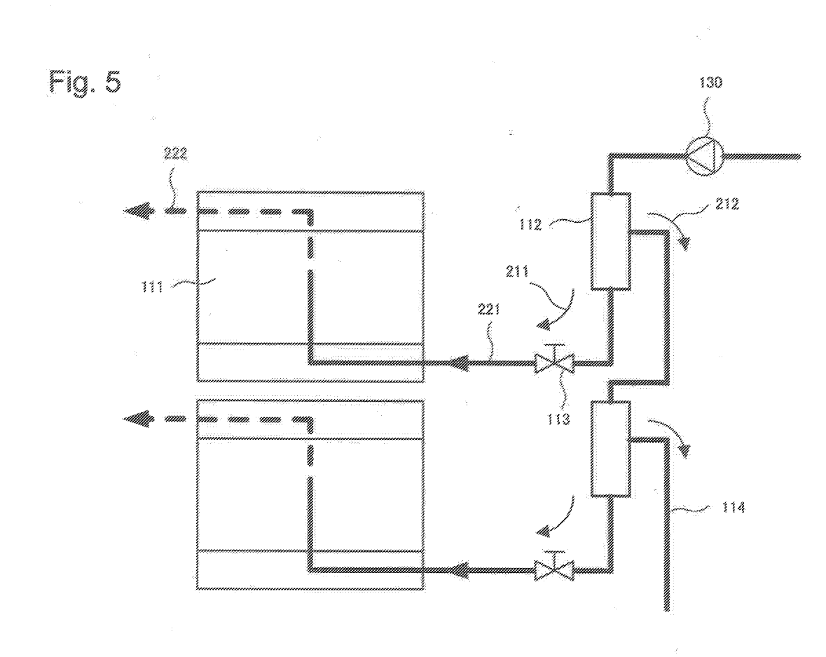

First, with reference to FIG. 5, circulation of the refrigerant in the heat reception unit module 110 will be described.

Each of the reserve tanks 112 includes an inlet into which the refrigerant liquid transported from the drive pump 130 flows, an outlet of which the refrigerant liquid flows out toward the heat reception unit 111, and a branch outlet connected with a branch pipe 114. From the outlet a portion of refrigerant liquid flows out, which is herein referred to as a heat reception unit refrigerant liquid flow 211, to be supplied to the heat reception unit 111 connected with the reserve tank 112. From the branch outlet a portion of the refrigerant flows out, which is herein referred to as a branch refrigerant liquid flow 212, when a certain volume of the refrigerant liquid is stored in the reserve tank 112, to be supplied through the branch pipe 114 to another reserve tank disposed in a lower position in a vertical direction.

The reserve tank 112 may be configured to have a capacity large enough at least to contain a volume of the refrigerant liquid such that the total amount of heat of evaporation of the volume of the refrigerant liquid is equal to the maximum amount of heat receivable by the heat reception unit 111. In other words, the reserve tank 112 may have a capacity large enough at least to store (reserve) an amount of refrigerant liquid calculated by dividing the maximum amount of heat to be exchanged in the heat reception unit 111 by the latent heat of the refrigerant. This allows the refrigerant liquid to be supplied in an appropriate amount in response to a change in the load on the electronic appliances 511.

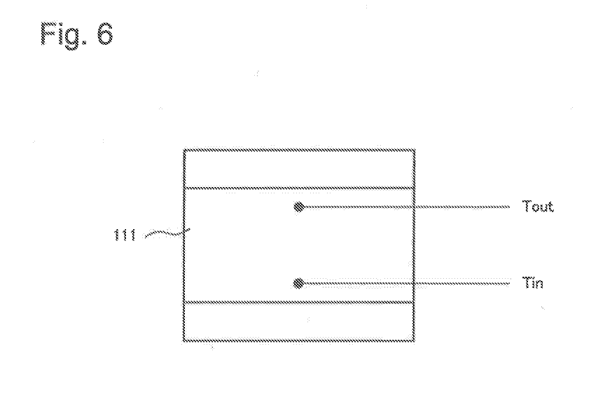

The refrigerant liquid 221 in the heat reception unit 111 exchanges heat with the heated air discharged by the electronic appliance 511, changes phase to become refrigerant vapor 222, and flows out to the vapor pipe 150. In FIG. 5, the discharged air flows in a direction perpendicular to the drawing plane. As illustrated in the drawing, the refrigerant liquid 221 flows into a lower part of the heat reception unit 111, changes to refrigerant vapor 222 and flows out from an upper part of the heat reception unit 111. FIG. 6 schematically illustrates the temperature distribution of the air discharged from a heat reception unit 111.

In FIG. 6, as in FIG. 5, the discharged air flows in a direction perpendicular to the drawing plane. The refrigerant liquid 221 flows into a lower part of the heat reception unit 111, changes to refrigerant vapor 222, and flows out from an upper part of the heat reception unit 111.

By supplying the heat reception unit 111 with the refrigerant liquid at a flow rate at which the latent heat of the refrigerant liquid supplied is equal to the heat to be exchanged in the heat reception unit 111, all the refrigerant liquid will have changed phase to gas to become refrigerant vapor by the time it flows out of the heat reception unit 111.

When the flow rate of the refrigerant liquid is smaller than in the above-described state, with the valve 113 at a smaller degree of opening, the discharged air temperature Tₒᵤₜ at the downstream side of the heat reception unit 111 illustrated in FIG. 6 becomes higher than the discharged air temperature Tᵢₙ at the upstream side because the refrigerant liquid that is to change phase is not sufficiently supplied. When the flow rate of the refrigerant liquid is greater than in the above-described state, with the valve 113 at a greater degree of opening, the refrigerant liquid that remains unevaporated but heated flows downstream and a temperature rise by sensible heat of the refrigerant liquid will occur in the downstream, the magnitude of the temperature rise being determined by the heat capacity of the refrigerant liquid. Hence, the discharged air temperature Tₒᵤₜ at the downstream side becomes higher than the discharged air temperature Tᵢₙ at the upstream side also in this case. As described above, when the flow rate of the refrigerant liquid is not optimal, the heat exchange performance deteriorates more badly in the parts further downstream of the heat reception unit 111. To avoid this, the degree of opening of the valve 113 is to be adjusted in such a way as to achieve the optimal flow rate of the refrigerant liquid by monitoring load information with respect to the electronic appliance 511 and temperature information with respect to the heat reception unit 111.

Next, with regard to a case in which the heat reception unit module 110 is provided with a plurality of heat reception units 111, a method of adjusting the degree of opening of valves 113 will be described in detail.

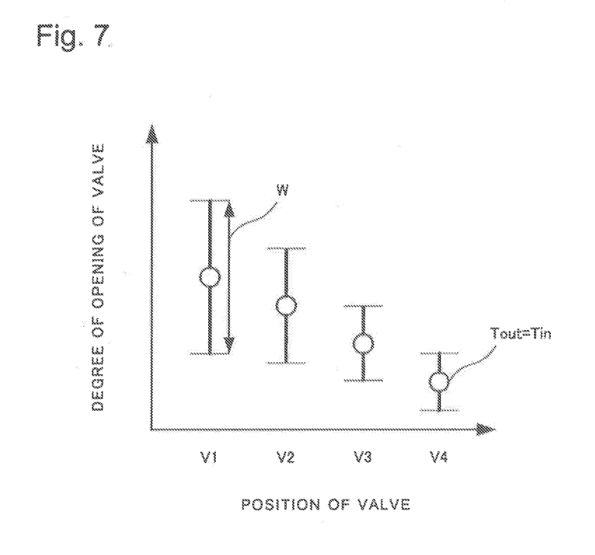

FIG. 7 illustrates an example of the relation between the degrees of opening of valves and the positions of valves in a heat reception unit module of a related art with no reserve tank. In this example, the heat reception unit module of a related art is provided with four heat reception units. In FIG. 7, the degrees of valve opening are laid out along the vertical axis whereas the vertical positions of valves are along the horizontal axis, lower positions being plotted further away from the origin. In other words valves V1, V2, V3, and V4 are disposed from top to bottom in a vertical direction in this order. W in the drawing indicates the range of adjustment of the degree of opening of each valve, and the hollow circles indicate the degree of opening of each valve at a time when the discharged air temperature Tₒᵤₜ at the downstream side of the heat reception unit is equal to the discharged air temperature Tᵢₙ at the upstream side (Tₒᵤₜ=Tᵢₙ), in other words, when the refrigerant liquid flows at an optimal flow rate.

When the load on an electronic appliance 511 changes, the refrigerant liquid no longer flows at an optimal flow rate at which the latent heat of the refrigerant liquid supplied is equal to the heat generated. In other words, as described above, when the load decrease, the flow rate becomes too great and the discharged air temperatures of the heat reception unit 111 will be Tₒᵤₜ>Tᵢₙ. When the load increases, the flow rate becomes too small and the discharged air temperatures of the heat reception unit 111 will be Tₒᵤₜ>Tᵢₙ. To avoid this, adjustment is to be made in such a way as to bring the degree of opening of each valve to the point indicated by the hollow circle (∘) to achieve Tₒᵤₜ=Tᵢₙ. More specifically, the degree of opening of the valve is reduced when the load decreases, and the degree of opening of the valve is increased when the load increases, to achieve Tₒᵤₜ=Tᵢₙ.

When the refrigerant liquid is supplied from an upper part of the rack 510, the refrigerant liquid flows from the upstream to the downstream. i.e., downward in a vertical direction as a portion of the refrigerant liquid changes phase to gas in each of the heat reception units 111. Thus smaller amounts of refrigerant liquid are supplied to the heat reception units 111 disposed in lower positions in a vertical direction. The degrees of opening of the valves are accordingly smaller in lower positions in a vertical direction. In addition, the degrees of opening of upstream valves need to be adjusted in response to the changes in the load on all the electronic appliances that exchange heat with the heat reception units disposed in the downstream. Because of this, a valve disposed further in the upstream needs a greater range of adjustment of the degree of opening, and the further in the upstream it is, the greater the range needs to be. In other words, a valve disposed further in the upstream has a smaller tolerance for degree of opening in responding changes in the load on the electronic appliances, and the further in the upstream it is, the smaller the tolerance is.

In contrast, the phase-change cooling apparatus 100 according to the present exemplary embodiment includes reserve tanks 112 respectively disposed in the upstream of the valves 113, the reserve tanks 112 serving as buffers by storing refrigerant in an amount sufficient for coping with changes in the load on the electronic appliances 511. This mitigates the above-described adverse effects of disposing plurality of heat reception units in a vertical direction.

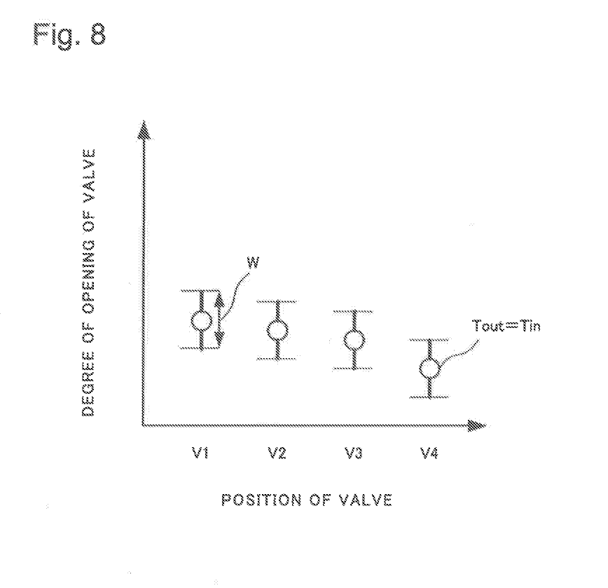

FIG. 8 illustrates an example of the relation between the degrees of opening of valves and the positions of valves in a heat reception unit module 110 included in the phase-change cooling apparatus 100 according to the present exemplary embodiment. In FIG. 8, the degrees of valve opening are laid out along the vertical axis whereas the vertical positions of valves arc along the horizontal axis, lower positions being plotted further away from the origin. W in the drawing indicates the range of adjustment of the degree of opening of each valve, and the hollow circles indicate the degree of opening of each valve at a time when the discharged air temperature Tₒᵤₜ at the downstream side of the heat reception unit is equal to the discharged air temperature Tₒᵤₜ at the upstream side (Tₒᵤₜ=Tᵢₙ), in other words, when the refrigerant liquid flows at an optimal flow rate.

As described above, the heat reception unit module 110 according to the present exemplary embodiment is provided with reserve tanks 112 respectively disposed in the upstream of the valves 113. Each of the reserve tanks 112 at least stores (reserves) an amount of refrigerant liquid that corresponds to the maximum amount of heat to be exchanged in the heat reception unit 111 and the refrigerant exceeding this reserve amount overflows to another reserve tank 112 disposed in the downstream. As this configuration allows refrigerant liquid to be supplied respectively from the reserve tanks 112 to heat reception units 111, valves disposed upstream have a large tolerance for degree of opening in responding to changes in the load on the electronic appliances, as illustrated in FIG. 8. Unlike with the configuration with no reserve tank as illustrated in FIG. 7, it is not the case that smaller amounts of refrigerant liquid are supplied to the heat reception units 111 disposed in lower positions. This mitigates dependency of the degrees of opening of the valves on the position of the valves.

As a result, even when the load on the electronic appliances abruptly changes, the supply of refrigerant can be adjusted in a short time, not deteriorating the heat exchange performance. In addition, the reliability of the cooling system is improved as the degrees of opening of the valves are adjusted to a smaller extent and less frequently.

As described above, the phase-change cooling apparatus 100 according to the present exemplary embodiment reduces the load on the air conditioner in the server room. This is because the refrigerant in the reserve tanks serves as a buffer to load changes on the servers, allowing for greater tolerance in response to load changes on the servers. Because of this, even when the load on the servers changes abruptly, there is no excess or shortage in the amount of supply of the refrigerant liquid, which prevents deterioration of heat absorbing performance.

Further, the phase-change cooling apparatus 100 according to the present exemplary embodiment enables improvement of the reliability of the cooling system. This is because, as described above, a large tolerance in response to load changes in the servers allows the adjustment of the degrees of opening of the valves to be done to a smaller extent and less frequently. This contributes to reducing the risk of failure of the driving components and prolonging the life of the valves.

### Third Exemplary Embodiment

Next, a third exemplary embodiment of the present invention will be described.

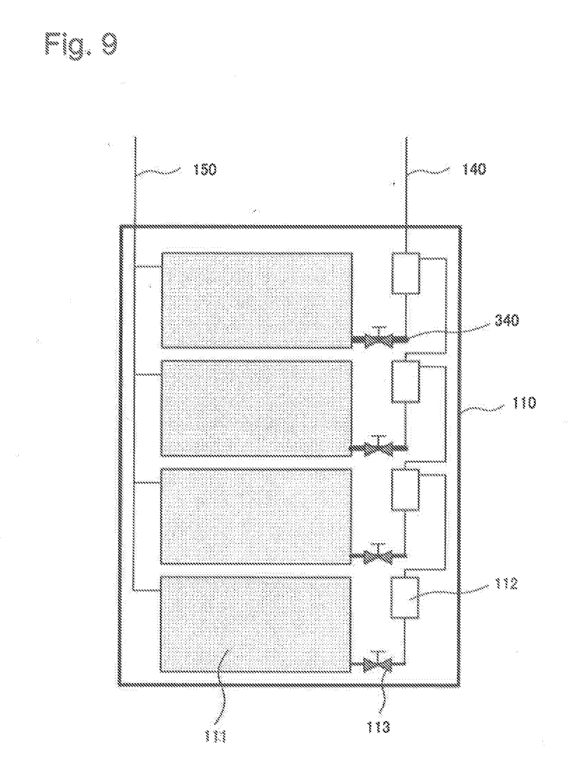

FIG. 9 illustrates a configuration of a heat reception unit module included in the phase-change cooling apparatus according to the present exemplary embodiment. As illustrated in FIG. 9, the heat reception unit module 110 according to the present exemplary embodiment includes valves 113 serving as refrigerant liquid amount adjustment means as well as heat reception unit liquid pipes 340 serving as pipes respectively connecting heat reception units 111 with reserve tanks 112 serving as reservoirs. The heat reception unit liquid pipes 340 are configured to include parts formed in such a way that the more downward a heat reception unit liquid pipe is located in a vertical direction, the smaller inner diameter the part of the heat reception unit liquid pipe has. More specifically, the heat reception unit liquid pipes 340 are configured to have consistently different inner diameters that depend on the vertical positions of the heat reception unit liquid pipes 340 or to include parts having such different inner diameters.

Such a configuration allows greater pressure losses in pipes disposed in lower positions in a vertical direction when the refrigerant liquid flowing from the liquid pipe 140 flows through the pipes. Therefore, the degrees of opening of the valves 113 can be made nearly uniform from the upstream to the downstream. This results in a further increased tolerance for the degree of valve opening in response to changes in the load on the electronic appliances 511, which allows simplification of the control system for adjusting the degrees of opening of the valves.

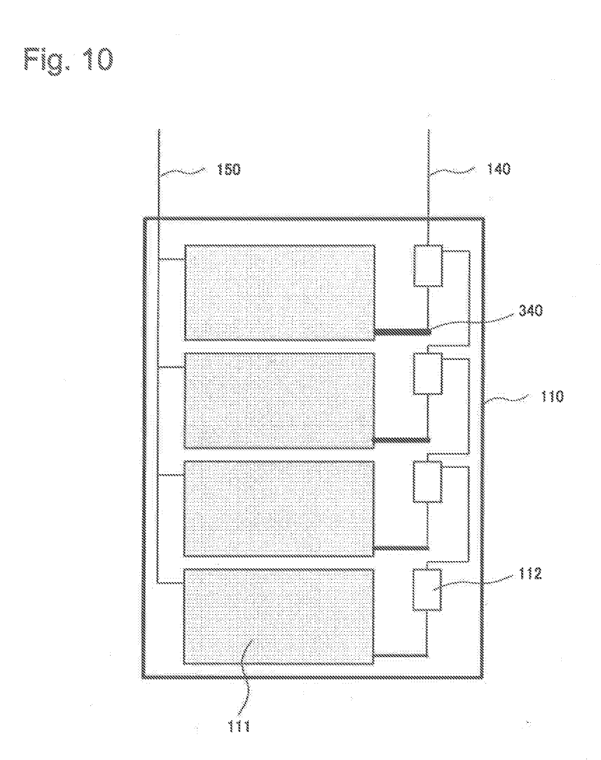

As illustrated in FIG. 10, the heat reception unit liquid pipes 340 may be provided without valves 113. Such a configuration allows greater pressure losses in pipes disposed in lower positions in a vertical direction when the refrigerant liquid flowing from the liquid pipe 140 flows through the pipes. In this case, pressure losses in the heat reception unit liquid pipes 340 take values respectively fixed for the heat reception units 111. Still, in cases in which the load conditions are predictable, for example, when the range of changes in the load on the electronic appliances 511 is small, operations without adjusting the degree of valve opening are feasible since load changes can be dealt with to a certain extent by the reserve tanks 112.

As described above, the phase-change cooling apparatus according to the present exemplary embodiment enables reduction of valve costs and cost of a control system for adjusting the degree of valve opening.

### Fourth Exemplary Embodiment

Next, a fourth exemplary embodiment of the present invention will be described.

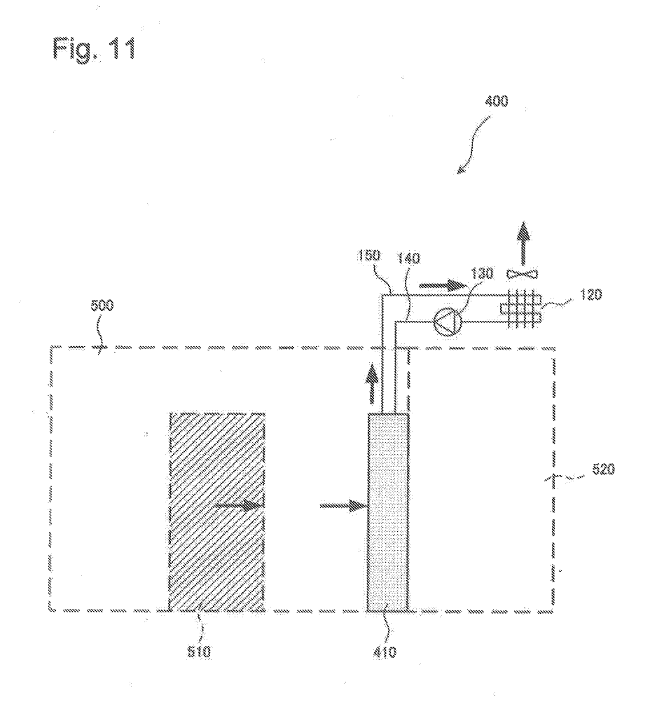

FIG. 11 is a schematic view illustrating an outline of a phase-change cooling apparatus 400 according to the present exemplary embodiment, disposed in a data center building. The phase-change cooling apparatus 400 according to the present exemplary embodiment is configured to have a plurality of heat reception units 111 disposed away from a housing containing an object to be cooled. In other words, the phase-change cooling apparatus 400 has a heat reception unit module 410 disposed, for example, on a wall of a server room 500, wherein the heat reception unit module 410 includes a plurality of heat reception units 111 and a plurality of refrigerant supply structures. The heat reception unit module 410 receives on the wall of the server room 500 heat discharged by electronic appliances 511, and the heat discharge unit 120 disposed outside the server room 500 discharges heat. The arrows in the drawing indicate the transportation of heat generated in the electronic appliances 511.

This configuration eliminates the need of providing a heat reception unit module for each of the racks 510. This reduces the initial investment cost for the cooling apparatus.

With the phase-change cooling apparatus according to the above-described embodiments, heat discharged from a rack containing a plurality of severs with changing loads, for example, in a data center can be transported to the outside of the server room by forced circulation, which allows reduction of power consumption by the air conditioner.

The present invention has been described above with above-described exemplary embodiments as exemplary examples. The present invention, however, is not limited to the above-described exemplary embodiments. In other words, various aspects of the present invention that a person skilled in the art can understand may be applied within the scope of the present invention.

The present application claims priority based on Japanese Patent Application No. 2015-051064 filed Mar. 13, 2015, the disclosure of which is herein incorporated by reference in its entirety.

### REFERENCE SIGNS LIST

10 refrigerant supply structure

11, 11X reservoir

11a inlet

11b outlet

11c branch outlet

12 refrigerant liquid amount adjustment means

13, 114 branch pipe

21 drive pump

22, 111 heat reception unit

100, 400 phase-change cooling apparatus

110, 410 heat reception unit module

112 reserve tank

113 valve

120 heat discharge unit

130 drive pump

140 liquid pipe

150 vapor pipe

211 heat reception unit refrigerant liquid flow

212 branch refrigerant liquid flow

221 refrigerant liquid

222 refrigerant vapor

340 heat reception unit liquid pipe

500 server room

510 rack

511 electronic appliance

520 machine room

1. A refrigerant supply device comprising:
a first reservoir for storing refrigerant liquid caused to flow by a drive pump; and
a refrigerant liquid amount adjustment unit adjusting a flow rate of the refrigerant liquid flowing out of the first reservoir to a heat reception unit,
wherein the reservoir comprises a branch outlet,
wherein the branch outlet is provided in a position higher than the refrigerant liquid amount adjustment unit, and
wherein refrigerant liquid stored in the first reservoir flows out of the branch outlet to a second reservoir disposed in a position lower than the first reservoir.

2. The refrigerant supply device according to claim 1, wherein the branch outlet is connected with a branch pipe for transporting refrigerant liquid in the first reservoir from a vicinity of the liquid surface of the refrigerant liquid in the first reservoir to the second reservoir.

3. The refrigerant supply device according to claim 1, wherein the refrigerant liquid amount adjustment unit is provided for a pipe connected to one of a bottom surface and a lower end of a side surface of the first reservoir.

4. The refrigerant supply device according to claim 1, wherein the refrigerant liquid amount adjustment unit controls a flow rate of the refrigerant liquid in such a way that the heat reception unit has substantially equal cooling characteristics at different points along a direction in which the refrigerant liquid flows.

5. The refrigerant supply device according to claim 1, wherein the refrigerant liquid amount adjustment unit is a variable flow valve.

6. The refrigerant supply device according to claim 1,
wherein the refrigerant liquid amount adjustment unit is a pipe connecting the heat reception unit with the first reservoir, and
wherein the pipe comprises a part having an inner diameter different from an inner diameter of another pipe connecting the second reservoir and another heat reception unit.

7. The refrigerant supply device according to claim 1,
wherein the first reservoir comprises an inlet into which the refrigerant liquid flows, an outlet of which refrigerant liquid flows out toward the heat reception unit, and a branch outlet connected with a branch pipe, and
wherein the refrigerant liquid amount adjustment unit is connected to the outlet.

8. The refrigerant supply device according to claim 1, wherein the first reservoir has a capacity large enough at least to contain a volume of the refrigerant liquid such that a total amount of heat of evaporation of the volume of the refrigerant liquid is equal to a maximum amount of heat receivable by the heat reception unit.

9. A phase-change cooling apparatus equipped with refrigerant supply devices, the apparatus comprising:
a plurality of heat reception units containing refrigerant and disposed in a vertical direction;
a heat discharge unit for discharging heat that the refrigerant receives in the heat reception unit, refrigerant liquid flowing out of the heat discharge unit;
a drive pump to cause the refrigerant liquid to flow; and
a plurality of refrigerant supply devices that respectively supply the refrigerant liquid to the plurality of heat reception unit,
wherein each of the refrigerant supply devices comprises:
a first reservoir for storing the refrigerant liquid caused to flow by the drive pump; and
a refrigerant liquid amount adjustment unit adjusting a flow rate of the refrigerant liquid flowing out of the first reservoir to a heat reception unit,
wherein the first reservoir comprises a branch outlet,
wherein the branch outlet is provided in a position higher than the refrigerant liquid amount adjustment unit, and
wherein refrigerant liquid stored in the first reservoir flows out of the branch outlet to a second reservoir disposed in a position lower than the first reservoir.

10. The phase-change cooling apparatus equipped with refrigerant supply devices according to claim 9, wherein the branch outlet is connected with a branch pipe for transporting refrigerant liquid in the first reservoir from a vicinity of the liquid surface of the refrigerant liquid in the first reservoir to the second reservoir.

11. The phase-change cooling apparatus equipped with refrigerant supply devices according to claim 9, wherein the refrigerant liquid amount adjustment unit is provided for a pipe connected to one of a bottom surface and a lower end of a side surface of the first reservoir.

12. The phase-change cooling apparatus equipped with refrigerant supply devices according to claim 9, wherein the refrigerant liquid amount adjustment units respectively control flow rates of the refrigerant liquid in such a way that the heat reception units respectively have substantially equal cooling characteristics at different points along a direction in which the refrigerant liquid flows.

13. The phase-change cooling apparatus equipped with refrigerant supply devices according to claim 9, wherein the refrigerant liquid amount adjustment unit is variable flow valve.

14. The phase-change cooling apparatus equipped with refrigerant supply devices according to claim 9,
wherein the refrigerant liquid amount adjustment units, are pipes respectively connecting the heat reception unit with the first reservoirs, and
wherein the pipes respectively comprise parts formed in such a way that the more downward a pipe is disposed in a vertical direction, the smaller inner diameter the part of the pipe has.

15. The phase-change cooling apparatus equipped with refrigerant supply devices according to claim 9, wherein the plurality of heat reception units are disposed in a housing containing an object to be cooled.

16. The phase-change cooling apparatus equipped with refrigerant supply devices according to claim 9, wherein the plurality of heat reception units are disposed away from a housing containing an object to be cooled.

17. A method of supplying refrigerant, the method comprising:
retaining reserve refrigerant liquid, which is refrigerant liquid caused to flow by a drive pump and stored;
controlling a flow rate of circulating refrigerant liquid, which is part of the reserve refrigerant liquid and flows to a heat reception region; and
causing part of the reserve refrigerant liquid to flow downward in a vertical direction from a vicinity of the liquid surface of the reserve refrigerant liquid.

18. The method of supplying refrigerant according to claim 17, wherein the flow rate of the circulating refrigerant liquid is controlled in such a way that the heat reception region has substantially equal cooling characteristics at different points along a direction in which the circulating refrigerant liquid flows.

19. The method of supplying refrigerant according to claim 17,
wherein the circulating refrigerant liquid is caused to flow toward each of a plurality of heat reception regions disposed in a vertical direction, and
wherein a control is performed in such a way that a heat reception region disposed in a lower position in a vertical direction has a greater pressure loss for the circulating refrigerant liquid flowing into the heat reception region and that the lower the position is, the greater the pressure loss is.
